(19) United States
(12) Patent Application Publication
(10) Pub. No.: US 2025/0048585 A1
(43) Pub. Date: Feb. 6, 2025

(54) HEAT DISSIPATION ASSEMBLY AND CONTROL METHOD AND APPARATUS THEREFOR, AND HEAT DISSIPATOR AND COMMUNICATION DEVICE

(71) Applicant: ZTE CORPORATION, Shenzhen (CN)

(72) Inventors: Xianming ZHANG, Shenzhen (CN); Daiyan LAN, Shenzhen (CN); Yue ZHU, Shenzhen (CN); Jie YANG, Shenzhen (CN); Jie QIAN, Shenzhen (CN); Wei DING, Shenzhen (CN)

(21) Appl. No.: 18/717,603

(22) PCT Filed: Dec. 5, 2022
(86) PCT No.: PCT/CN2022/136640

§ 371 Date: Jun. 7, 2024

(30) Foreign Application Priority Data
Dec. 8, 2021 (CN) 202111493916.1

(51) Int. Cl. H05K 7/20

(52) U.S. Cl. CPC H05K 7/20172

(57) ABSTRACT

Disclosed are a heat dissipation assembly and a control method therefor, an apparatus, a heat dissipator, and a communication device. The heat dissipation assembly may include: a vibration plate unit, provided with a vibration plate and at least one piezoelectric sheet connected to the vibration plate; and a drive unit, electrically connected to the vibration plate unit, and the drive unit is configured to: adjust, in response to meeting a trigger condition, a first driving frequency output to the piezoelectric sheet within a preset frequency range to obtain a plurality of corresponding first output currents, determine a target driving frequency based on the plurality of first output currents, and apply a driving voltage to the piezoelectric sheet based on the target driving frequency.

### CROSS-REFERENCE TO RELATED APPLICATION

This application is a national stage filing under 35 U.S.C. § 371 of international application number PCT/CN2022/136640, filed Dec. 5, 2022, which claims priority to Chinese patent application No. 202111493916.1 filed Dec. 8, 2021. The contents of these applications are incorporated herein by reference in their entirety.

### TECHNICAL FIELD

The present disclosure relates to the technical field of electronic heat dissipation, and more particularly, to a heat dissipation assembly and a control method therefor, an apparatus, a heat dissipator, and a communication device.

### BACKGROUND

Electronic products generate a large amount of heat during operation. To ensure product reliability, an effective heat dissipation method is needed to control temperature rise. With increasing demands for miniaturization and integration of electronic products, natural heat dissipation methods often cannot provide efficient temperature control. For example, for a Remote Radio Unit (RRU) or an Active Antenna Unit (AAU) of an outdoor communication base station, its mainstream heat dissipation method is natural heat dissipation (heat dissipation through heat dissipation fins). However, as power consumption of the RRU or the AAU increases continuously, a heat dissipation volume of the devices also needs to increase. Therefore, an active cooling method using forced air cooling is needed to reduce the size and weight of the device.

A piezoelectric vibration fan is suitable to forced air cooling of the RRU or the AAU of the outdoor communication base station due to its high reliability, low noise, low power consumption, high temperature resistance, and small installation space. However, for a piezoelectric vibration fan in the related art, after prolonged use, the amplitude of the vibration plate is significantly reduced, greatly weakening its heat dissipation capability.

### SUMMARY

The present disclosure proposes a heat dissipation assembly and a control method therefor, an apparatus, a heat dissipator, and a communication device.

In accordance with a first aspect of the present disclosure, an embodiment provides a heat dissipation assembly, including a vibration plate unit and a drive unit, the vibration plate unit is provided with a vibration plate, and at least one piezoelectric sheet connected to the vibration plate, the drive unit is electrically connected to the vibration plate unit and is configured to: adjust, in response to meeting a trigger condition, a first driving frequency output to the piezoelectric sheet within a preset frequency range to obtain a plurality of corresponding first output currents, determine a target driving frequency based on the plurality of first output currents, and apply a driving voltage to the piezoelectric sheet based on the target driving frequency.

In accordance with a second aspect of the present disclosure, an embodiment provides a heat dissipator, including the heat dissipation assembly described in the embodiment of the first aspect of the present disclosure.

In accordance with a third aspect of the present disclosure, an embodiment provides a control method for a heat dissipation assembly, the heat dissipation assembly is provided with a vibration plate unit and a drive unit electrically connected to the vibration plate unit, and the vibration plate unit is provided with a vibration plate and at least one piezoelectric sheet connected to the vibration plate, the control method for a heat dissipation assembly includes: adjusting, in response to meeting a trigger condition, a first driving frequency output to the piezoelectric sheet within a preset frequency range to obtain a plurality of corresponding first output currents; determining a target driving frequency based on the plurality of first output currents; and applying a driving voltage to the piezoelectric sheet based on the target driving frequency.

In accordance with a fourth aspect of the present disclosure, an embodiment provides a communication device, including the heat dissipation assembly described in the embodiment of the first aspect of the present disclosure or the heat dissipator described in the embodiment of the second aspect of the present disclosure.

In accordance with a fifth aspect of the present disclosure, an embodiment provides an operation control apparatus, including at least one control processor and a memory configured to be communicatively connected to the at least one control processor, the memory stores instructions executable by the at least one control processor which, when executed by the at least one control processor, causes the at least one control processor to carry out the control method for a heat dissipation assembly described in the embodiment of the third aspect of the present disclosure.

In accordance with a sixth aspect of the present disclosure, an embodiment provides a computer-readable storage medium, storing computer-executable instructions which, when executed by a computer, causes the computer to carry out the control method for a heat dissipation assembly described in the embodiment of the third aspect of the present disclosure.

Additional features and advantages of the present disclosure will be set forth in the description which follows, and in part will be apparent from the description, or may be learned by the practice of the present disclosure. The objects and other advantages of the present disclosure can be realized and obtained by the structures particularly pointed out in the description, claims, and drawings.

### BRIEF DESCRIPTION OF DRAWINGS

The drawings are provided for a further understanding of the technical schemes of the present disclosure, and constitute a part of the description. The drawings and the embodiments of the present disclosure are used to illustrate the technical schemes of the present disclosure, and are not intended to limit the technical schemes of the present disclosure.

The present disclosure is further described below in conjunction with the accompanying drawings and embodiments.

FIG. 1 is a schematic structural diagram of a heat dissipation assembly according to an embodiment of the present disclosure;

FIG. 2 is a schematic structural diagram of a vibration plate unit with two piezoelectric sheets according to another embodiment of the present disclosure;

FIG. 3 is a schematic structural diagram of a vibration plate unit with a single piezoelectric sheet according to another embodiment of the present disclosure;

FIG. 4 is a schematic structural diagram of a heat dissipation assembly provided with 2N vibration plate units according to another embodiment of the present disclosure;

FIG. 5 is a schematic structural diagram of a heat dissipation assembly provided with 2N+1 vibration plate units according to another embodiment of the present disclosure;

FIG. 6 is a schematic structural diagram of a heat dissipation assembly with vibration plate units arranged in a two-dimensional array according to another embodiment of the present disclosure;

FIG. 7 is a schematic diagram of an array arrangement of vibration plate units along a first direction of a fastening structure according to another embodiment of the present disclosure;

FIG. 8 is a schematic diagram of an array arrangement of vibration plate units along a second direction of a fastening structure according to another embodiment of the present disclosure;

FIG. 9 is a schematic structural diagram of a heat dissipator according to an embodiment of the present disclosure;

FIG. 10 is a schematic structural diagram of a heat dissipator according to another embodiment of the present disclosure;

FIG. 11 is a flowchart of a control method for a heat dissipation assembly according to an embodiment of the present disclosure;

FIG. 12 is a flowchart of a control method for a heat dissipation assembly according to another embodiment of the present disclosure;

FIG. 13 is a flowchart of a control method for a heat dissipation assembly according to another embodiment of the present disclosure;

FIG. 14 is a flowchart of a control method for a heat dissipation assembly according to another embodiment of the present disclosure; and

FIG. 15 is a schematic structural diagram of an operation control apparatus according to an embodiment of the present disclosure.

### DETAILED DESCRIPTION

This section will describe in detail some embodiments of the present disclosure. Some embodiments of the present disclosure are shown in the accompanying drawings. The accompanying drawings are used to supplement the descriptions of the specification with graphics, such that people can understand each technical feature and the overall technical scheme of the present disclosure intuitively and vividly, but they shall not be understood as limiting the protection scope of the present disclosure.

In the descriptions of the present disclosure, “several” means one or more, “a plural of/multiple” means two or more, “greater than”, “less than”, “exceed” or variants thereof prior to a number or series of numbers is understood to not include the number adjacent to the term, and “above”, “below”, “within”, and the like are understood to include the number. If used herein, the terms such as “first”, “second”, and the like are merely used for distinguishing technical features, and are not intended to indicate or imply relative importance, or implicitly point out the number of the indicated technical features, or implicitly point out the precedence order of the indicated technical features.

In the descriptions of the present disclosure, unless otherwise explicitly limited, terms such as “arrange”, “install”, and “connect” should be understood in a broad sense. Those having ordinary skills in the art can properly determine meanings of the terms in the present disclosure based on contents of the technical schemes.

A fan is a device that blows air. A commonly-used conventional rotary fan is limited duration application in outdoor scenes due to its unsatisfactory reliability, large noise, and high energy consumption caused by characteristics of a bearing and a blade. A piezoelectric vibration fan is applicable to forced air cooling of an RRU or an AAU of an outdoor communication base station due to its technical characteristics of high reliability, low noise, low power consumption, high temperature resistance, and small installation space.

In some embodiments, for practical application of piezoelectric vibration fans in heat dissipation by forced air cooling, piezoelectric vibration fans in the related art generally use a fixed-frequency driving mode. A fan vibration plate is fatigued after operating under long-term alternating stress. As a result, stiffness changes, and a natural frequency of the piezoelectric vibration fan shifts. In addition, in some specific environments, when foreign matter adheres to the fan vibration plate, the natural frequency of the system may also change, causing a fundamental frequency of the piezoelectric vibration fan to drift. Consequently, an amplitude is significantly reduced, and a heat dissipation capability is weakened. Typically, the natural frequency of the system changes due to accumulation of dust, grease, or catkins on the fan vibration plate. In this case, if the fixed-frequency driving mode is still used, a resonance phenomenon cannot occur. Consequently, an amplitude of the vibration plate becomes smaller, and a heat dissipation capability is weakened.

Embodiments of the present disclosure provide a heat dissipation assembly, a control method therefor, an apparatus, a heat dissipator, and a communication device, which can intelligently adjust a target driving frequency output to a piezoelectric sheet, to increase an amplitude of a vibration plate, and greatly improve a heat dissipation capability.

The embodiments of the present disclosure will be described blow in conjunction with the accompanying drawings.

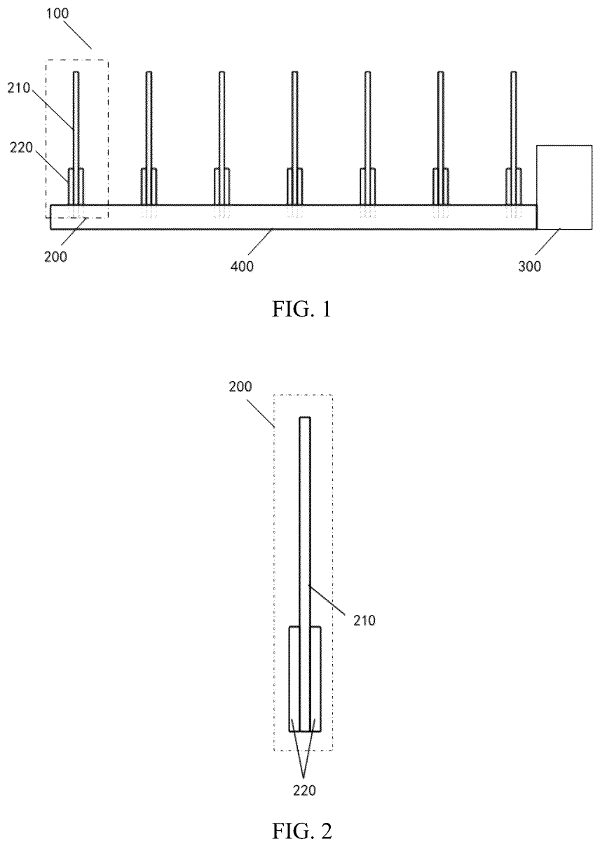

As shown in FIG. 1, an embodiment of a first aspect of the present disclosure provides a heat dissipation assembly 100, including a vibration plate unit 200 and a drive unit 300. The vibration plate unit 200 is provided with a vibration plate 210, and at least one piezoelectric sheet 220 connected to the vibration plate 210. The drive unit 300 is electrically connected to the vibration plate unit 200, and the drive unit 300 is configured to: when a trigger condition is met, adjust a first driving frequency output to the piezoelectric sheet 220 within a preset frequency range to obtain a plurality of corresponding first output currents, determine a target driving frequency based on the plurality of first output currents, and apply a driving voltage to the piezoelectric sheet 220 based on the target driving frequency.

In this embodiment, the vibration plate unit 200 is formed by connecting the vibration plate 210 and the piezoelectric sheet 220. When a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210 to increase a wind speed of the heat dissipation assembly 100, and greatly improve a heat dissipation capability.

It should be noted that a resonance phenomenon is that when a frequency of an input driving voltage is equal to a natural frequency of the vibration plate unit 200, an overhanging end of the vibration plate 210 reaches a maximum amplitude. Different from a fixed-frequency driving mode used in some cases, the heat dissipation assembly 100 in this embodiment of the present disclosure uses a driving mode of automatic frequency training. The drive unit 300 may adjust the driving frequency based on a status of the heat dissipation assembly 100. When the natural frequency changes, the target driving frequency output to the piezoelectric sheet 220 can be intelligently adjusted to be consistent with the natural frequency, such that the vibration plate 210 always maintains a maximum amplitude under a resonance condition, which improves a heat dissipation effect and resolves drift of a fundamental frequency caused by the conventional natural-frequency driving mode.

It should be noted that the piezoelectric sheet 220 is made of a piezoelectric ceramic material, the vibration plate 210 is made of an elastic material, and the piezoelectric sheet 220 is bonded to the vibration plate 210 to form the vibration plate unit 200. The drive unit 300 applies an alternating voltage (a periodically changing direct current) to the piezoelectric sheet 220, and the piezoelectric sheet 220 performs periodic contraction based on an inverse piezoelectric effect of the piezoelectric material, which drives the vibration plate 210 to oscillate periodically, thereby driving fluid nearby to flow directionally.

In an embodiment, the drive unit 300 uses an intermittent direct current to drive the piezoelectric sheet 220. When the target driving frequency is close to the natural frequency of the vibration plate unit 200, the piezoelectric sheet 220 can drive the vibration plate 210 to vibrate to generate an objective directional wind speed, thereby ensuring a satisfactory heat dissipation effect.

It can be understood that the heat dissipation assembly 100 is a piezoelectric vibration fan. Since the heat dissipation assembly 100 generates a wind speed through oscillation of the vibration plate 210, heat exchange efficiency of a heat dissipator can be effectively improved. In addition, there are no bearing parts in the heat dissipation assembly 100, which helps improve reliability of the heat dissipation assembly 100, and is different from a conventional rotary fan used in some cases. The heat dissipation assembly 100 in this embodiment of the present disclosure effectively reduces system noise, resolves a problem of unsatisfactory heat dissipation capability of a conventional heat dissipation method for an outdoor communication device while ensuring reliability, and achieves a significant decrease in the size and weight of the communication device.

In the heat dissipation assembly 100, determining a target driving frequency based on the plurality of first output currents includes:
determining a current extremum based on the plurality of first output currents; and
determining a corresponding target driving frequency based on the current extremum.

In this embodiment, the drive unit 300 continually changes the first driving frequency within the given preset frequency range, records and stores corresponding first output currents at first driving frequencies, determines a current extremum (a maximum value or a minimum value of the currents) based on the plurality of obtained first output currents, a target driving frequency corresponding to the current extremum being a better frequency, and applies a driving voltage to the piezoelectric sheet 220 based on the target driving frequency.

It should be noted that it is found through experiments that within the given frequency range, the driving frequency corresponding to the current extremum leads to a maximum amplitude of the vibration plate 210 and a maximum wind speed of the heat dissipation assembly 100, thereby improving a heat dissipation effect. Therefore, the target driving frequency is a better frequency.

In the heat dissipation assembly 100, the trigger condition includes at least one of the following that:
the heat dissipation assembly 100 is started; or
a second output current of the drive unit 300 is detected when the heat dissipation assembly 100 operates continuously, and a difference between the second output current and the current extremum exceeds a preset difference range; or
a continuous operation time of the heat dissipation assembly 100 reaches a preset time period after the target driving frequency is determined each time.

In this embodiment, the trigger condition is added for the drive unit 300 to search for a better frequency. Only when the trigger condition is met, the drive unit 300 searches for the target driving frequency, which can ensure operation stability of the heat dissipation assembly 100. The trigger condition may be met in the following three cases:

1. The drive unit 300 is triggered once each time the heat dissipation assembly 100 is started.

2. When the heat dissipation assembly 100 operates continuously, the drive unit 300 regularly detects the second output current, and compares the second output current with the internally stored current extremum. When a difference between the detected second output current and the stored current extremum exceeds the specified preset difference range, the drive unit 300 is triggered to perform the action of searching for a better frequency.

3. When the heat dissipation assembly 100 operates continuously, based on the preset time period, the drive unit 300 is triggered to perform the action of searching for a better frequency each time one preset time period elapses, that is, triggered once when a continuous operation time reaches the preset time period after the target driving frequency is determined each time.

As shown in FIG. 1, the heat dissipation assembly 100 further includes a fastening structure 400. The vibration plate unit 200 is connected to the fastening structure 400, and the vibration plate 210 has one end connected to the fastening structure 400 and the other end overhanging.

In this embodiment, the fastening structure 400 provides a boundary fastening condition for the vibration plate unit 200. The vibration plate unit 200 may be fastened to the fastening structure 400 by injection molding or mechanical crimping, to ensure operation stability of the vibration plate 210.

It should be noted that the drive unit 300 may be independent of the vibration plate unit 200 and the fastening structure 400 such that the vibration plate unit 200, the fastening structure 400, and the drive unit 300 form a split heat dissipation assembly 100, or may be integrated into the fastening structure 400 such that the vibration plate unit 200, the fastening structure 400, and the drive unit 300 form an integrated heat dissipation assembly 100.

In the heat dissipation assembly 100, the piezoelectric sheet 220 is arranged at an end of the vibration plate 210 connected to the fastening structure 400. The vibration plate 210 can oscillate periodically as driven by the piezoelectric sheet 220, to generate a wind speed, thereby ensuring a satisfactory heat dissipation effect.

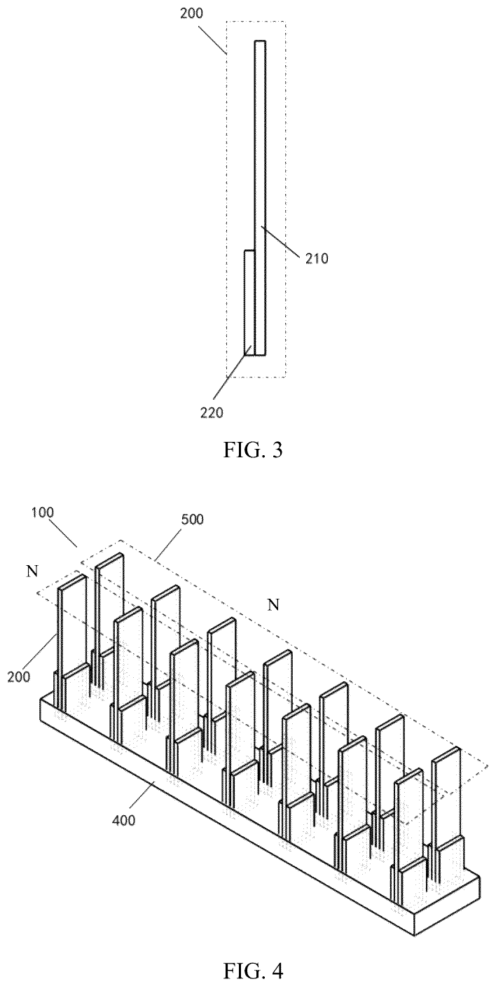

As shown in FIG. 2 and FIG. 3, in the heat dissipation assembly 100, one side of the vibration plate 210 is provided with the piezoelectric sheet 220, or two sides of the vibration plate 210 are both provided with the piezoelectric sheet 220.

As shown in FIG. 2 and FIG. 3, in this embodiment, the vibration plate unit 200 may be formed by connecting one piezoelectric sheet 220 to one side of the vibration plate 210, or may be formed by connecting one piezoelectric sheet 220 to each of the two sides of the vibration plate 210. When two piezoelectric sheets 220 are arranged on the two sides of the vibration plate 210, the vibration plate unit 200 can generate a greater driving force, to increase the wind speed of the heat dissipation assembly 100.

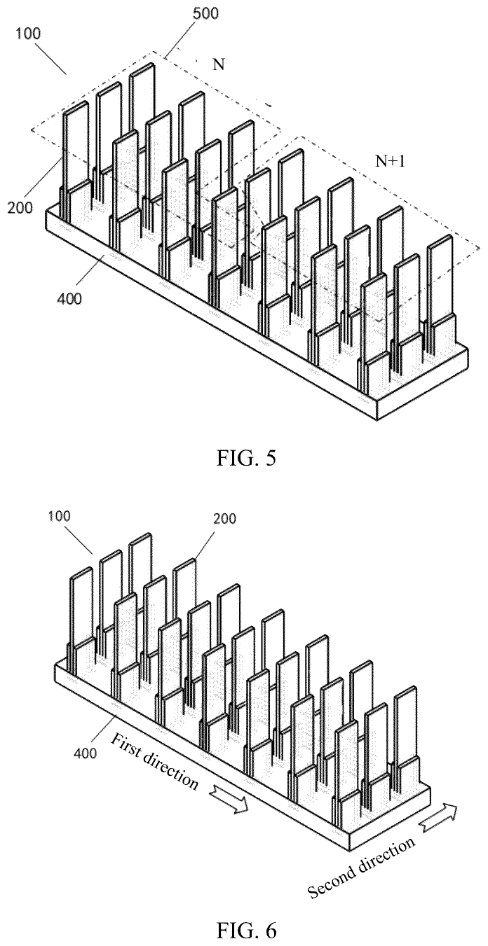

As shown in FIG. 4, in the heat dissipation assembly 100, 2N vibration plate units 200 are provided and divided into two vibration plate arrays 500 each including N vibration plate units 200, and the drive unit 300 is further configured to apply driving signals with opposite phases to the vibration plate units 200 located in different arrays respectively, where N≥1.

In this embodiment, when an even number (2N) of vibration plate units 200 are arranged, the 2N vibration plate units 200 may be divided into two vibration plate arrays 500 each including N vibration plate units 200. During driving, the drive unit 300 respectively applies driving signals with opposite phases to the vibration plate units 200 in different arrays. By controlling phase values of driving signals applied to different vibration plate units 200, symmetrical vibration can be formed to reduce overall vibration of the heat dissipation assembly 100, thereby reducing noise generated by resonance between the heat dissipation assembly 100 and a heat dissipator 600. It should be noted that in this embodiment of the present disclosure, a selection method for the N vibration plate units 200 in each array is not limited. For example, N adjacent vibration plate units 200 may be selected, or N vibration plate units 200 may be selected alternately.

As shown in FIG. 5, in the heat dissipation assembly 100, 2N+1 vibration plate units 200 are provided and divided into two vibration plate arrays 500. The two vibration plate arrays 500 respectively include N+1 vibration plate units 200 and N vibration plate units 200, and the drive unit 300 is further configured to apply driving signals with opposite phases to vibration plate units 200 located in different arrays respectively, where N≥1.

In this embodiment, when an odd number (2N+1) of vibration plate units 200 are arranged, the 2N+1 vibration plate units 200 may be divided into two vibration plate arrays 500, with one array including include N+1 vibration plate units 200, and the other array including N vibration plate units 200. During operation, the drive unit 300 applies driving signals with opposite phases to the vibration plate units 200 in different arrays, respectively. By controlling phase values of driving signals applied to different vibration plate units 200, symmetrical vibration can be formed to reduce overall vibration of the heat dissipation assembly 100, thereby reducing noise generated by resonance between the heat dissipation assembly 100 and a heat dissipator 600.

It should be noted that a plurality of vibration plate units 200 are arranged. In this embodiment of the present disclosure, two forms, namely, an even number of vibration plate units 200 and an odd number of vibration plate units 200 are adopted. The vibration plate units 200 are divided into two arrays, and driving voltages with opposite phases are respectively applied thereto, which can greatly reduce operating noise.

It should be noted that the drive unit 300 adjusts a frequency during operation. In this embodiment of the present disclosure, the number of drive units 300 is not limited. For example, each vibration plate unit 200 may have one drive unit 300 configured, or a plurality of vibration plates 210 may share one drive unit 300, to form the heat dissipation assembly 100 of the present disclosure.

As shown in FIG. 6, in the heat dissipation assembly 100, a plurality of vibration plate units 200 are provided and arranged in an array along a first direction and a second direction of the fastening structure 400.

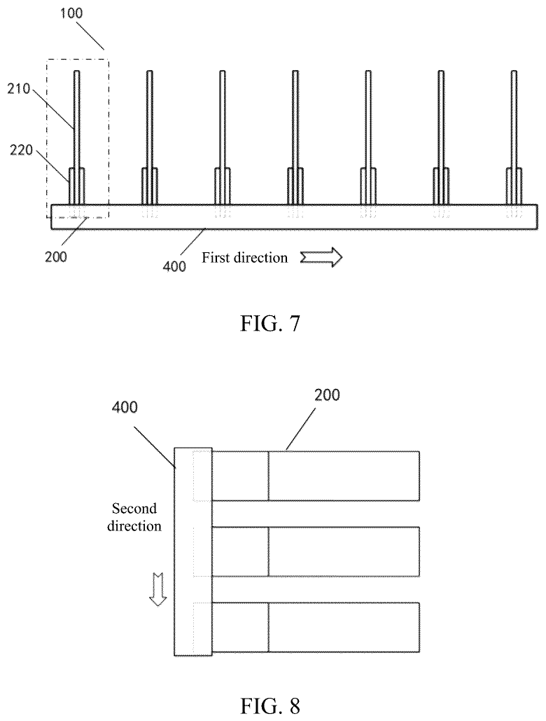

As shown in FIG. 6 to FIG. 8, in this embodiment, the heat dissipation assembly 100 includes a plurality of vibration plate units 200 arranged in an array. The vibration plate units 200 are arranged on the fastening structure 400 in an array including two direction dimensions. FIG. 7 is a schematic diagram of an array arrangement of the vibration plate units 200 along the first direction of the fastening structure 400. FIG. 8 is a schematic diagram of an array arrangement of the vibration plate units 200 along the second direction of the fastening structure 400. Through the array arrangement along the first direction and the second direction of the fastening structure 400, the plurality of vibration plate units 200 are arranged in a two-dimensional array structure on the fastening structure 400, to form the heat dissipation assembly 100 shown in FIG. 6, which can increase an air outlet area of the heat dissipation assembly 100, to help improve heat dissipation performance, and resolve a problem that a wind speed of a conventional piezoelectric vibration fans attenuates excessively quickly in heat dissipation fins.

An embodiment of a second aspect of the present disclosure provides a heat dissipator 600, including the heat dissipation assembly 100 in the foregoing embodiments.

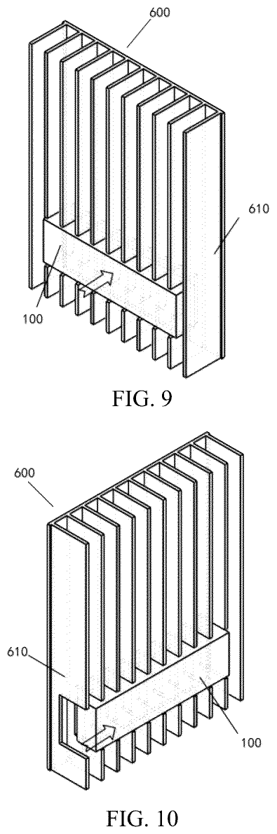

As shown in FIG. 1, FIG. 9, and FIG. 10, the heat dissipator 600 provided in this embodiment is provided with the heat dissipation assembly 100. The heat dissipation assembly 100 includes a vibration plate unit 200 and a drive unit 300. The vibration plate unit 200 is formed by connecting a vibration plate 210 and a piezoelectric sheet 220. When a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210, increase a wind speed of the heat dissipation assembly 100, and greatly improve a heat dissipation capability.

As shown in FIG. 9 and FIG. 10, the heat dissipator 600 is provided with a base 610, and the heat dissipation assembly 100 is mounted on the heat dissipator 600 along a normal direction of the base 610, or the heat dissipation assembly 100 is mounted on the heat dissipator 600 along a direction parallel to the base 610.

In this embodiment, the heat dissipator 600 is provided with a base 610, and the heat dissipation assembly 100 may be mounted and fastened on the heat dissipator 600 in two manners: perpendicular to the base 610 or parallel to the base 610. The two manners are described as follows.

Manner one: As shown in FIG. 9, the heat dissipation assembly 100 is mounted and fastened along the normal direction of the base 610, that is, mounted along a depth direction of the heat dissipator 600, which can be flexibly located at any height in the normal direction of the base 610, making it easy to install and having satisfactory stability and reliability.

Manner two: As shown in FIG. 10, the heat dissipation assembly 100 is mounted and fastened sideways along the direction parallel to the base 610, that is, located and mounted along a width direction of the heat dissipator 600, which facilitates installation and replacement of the heat dissipation assembly 100.

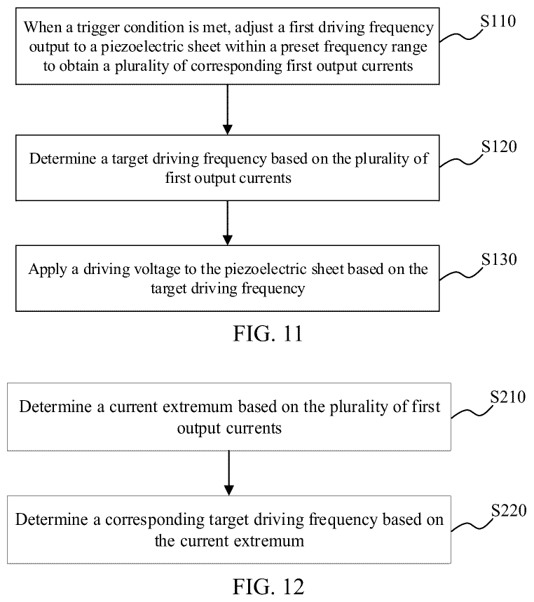

As shown in FIG. 1 and FIG. 11, an embodiment of a third aspect of the present disclosure provides a control method for a heat dissipation assembly. The heat dissipation assembly 100 is provided with a vibration plate unit 200 and a drive unit 300 electrically connected to the vibration plate unit 200, and the vibration plate unit 200 is provided with a vibration plate 210 and at least one piezoelectric sheet 220 connected to the vibration plate 210. The control method for a heat dissipation assembly includes, but not limited to, the following steps S110 to S130.

At S110, when a trigger condition is met, a first driving frequency output to the piezoelectric sheet is adjusted within a preset frequency range to obtain a plurality of corresponding first output currents.

At S120, a target driving frequency is determined based on the plurality of first output currents.

At S130, a driving voltage is applied to the piezoelectric sheet based on the target driving frequency.

In this embodiment, the vibration plate unit 200 is formed by connecting the vibration plate 210 and the piezoelectric sheet 220. When a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210 to increase a wind speed of the heat dissipation assembly 100, and greatly improve a heat dissipation capability.

It should be noted that the drive unit 300 applies an alternating voltage (a periodically changing direct current) to the piezoelectric sheet 220, such that the piezoelectric sheet 220 drives the vibration plate 210 to oscillate periodically, thereby generating an air flow. In the control method for a heat dissipation assembly in this embodiment of the present disclosure, a driving mode of automatic frequency training is used. The drive unit 300 may be controlled to adjust the driving frequency based on a status of the heat dissipation assembly 100. When a natural frequency of the heat dissipation assembly 100 changes, the target driving frequency output to the piezoelectric sheet 220 can be intelligently adjusted to be close to the natural frequency, such that an amplitude of the vibration plate 210 is maximized as much as possible, which helps improve a heat dissipation effect and resolves drift of a fundamental frequency caused by a conventional fixed-frequency driving mode.

As shown in FIG. 12, in the control method for a heat dissipation assembly, determining a target driving frequency based on the plurality of first output currents at S120 includes, but not limited to, the following steps S210 and S220:

At S210, a current extremum is determined based on the plurality of first output currents.

At S220, a corresponding target driving frequency is determined based on the current extremum.

In this embodiment, the drive unit 300 continually changes the first driving frequency f within the given preset frequency range, records and stores corresponding first output currents I₁ at first driving frequencies f, determines a current extremum I₀ (a maximum value or a minimum value of the currents) based on the plurality of obtained first output currents I₁, a target driving frequency f₀ corresponding to the current extremum I₀ being a better frequency, and applies a driving voltage to the piezoelectric sheet 220 based on the target driving frequency f₀.

In the control method for a heat dissipation assembly, the trigger condition includes at least one of the following that:
the heat dissipation assembly 100 is started; or
a second output current I₂ of the drive unit 300 is detected when the heat dissipation assembly 100 operates continuously, and a difference between the second output current I₂ and the current extremum I₀ exceeds a preset difference range; or
a continuous operation time of the heat dissipation assembly 100 reaches a preset time period after the target driving frequency f₀ is determined each time.

In this embodiment, the trigger condition is added for the drive unit 300 to search for a better frequency. Only when the trigger condition is met, the drive unit 300 searches for the target driving frequency f₀, which can ensure operation stability of the heat dissipation assembly 100. Conditions for triggering the search for a better frequency include: 1. The drive unit 300 is triggered once each time the heat dissipation assembly 100 is started. 2. When the heat dissipation assembly 100 operates continuously, the drive unit 300 regularly detects the second output current I₂, and compares the second output current I₂ with the internally stored current extremum I₀. When a difference between the detected second output current I₂ and the stored current extremum I₀ exceeds the specified preset difference range, the drive unit 300 is triggered to perform the action of searching for a better frequency. 3. When the heat dissipation assembly 100 operates continuously, based on the preset time period T, the drive unit 300 is triggered to perform the action of searching for a better frequency each time one preset time period T elapses, that is, triggered once when a continuous operation time reaches the preset time period T after the target driving frequency f₀ is determined each time.

Two embodiments of the control method for a heat dissipation assembly in the present disclosure are described below.

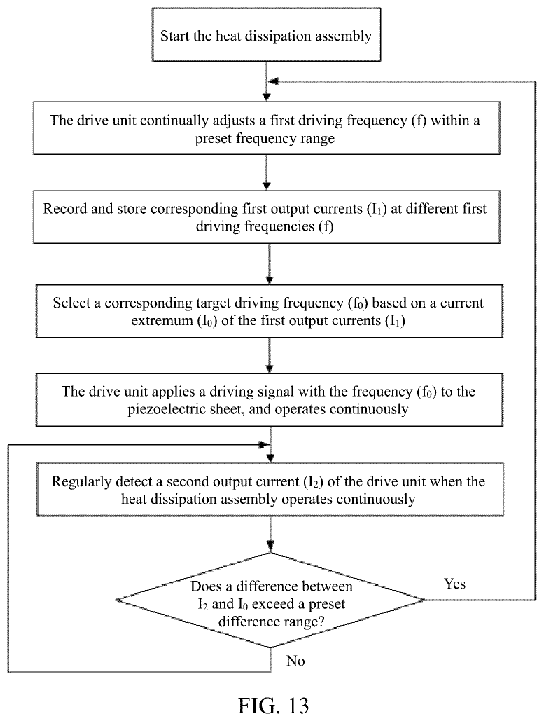

Embodiment one: As shown in FIG. 13, the heat dissipation assembly is started, and the drive unit continually adjusts a first driving frequency f within a preset frequency range, records and stores corresponding first output currents I₁ at different first driving frequencies f, and selects a corresponding target driving frequency f₀ based on a current extremum I₀ of the first output currents I₁. The drive unit applies a driving signal with the frequency f₀ to the piezoelectric sheet, operates continuously, regularly detects a second output current I₂ of the drive unit when the heat dissipation assembly operates continuously, and when a difference between the second output current I₂ and the stored current extremum I₀ exceeds a preset difference range, searches for a target driving frequency f₀ again.

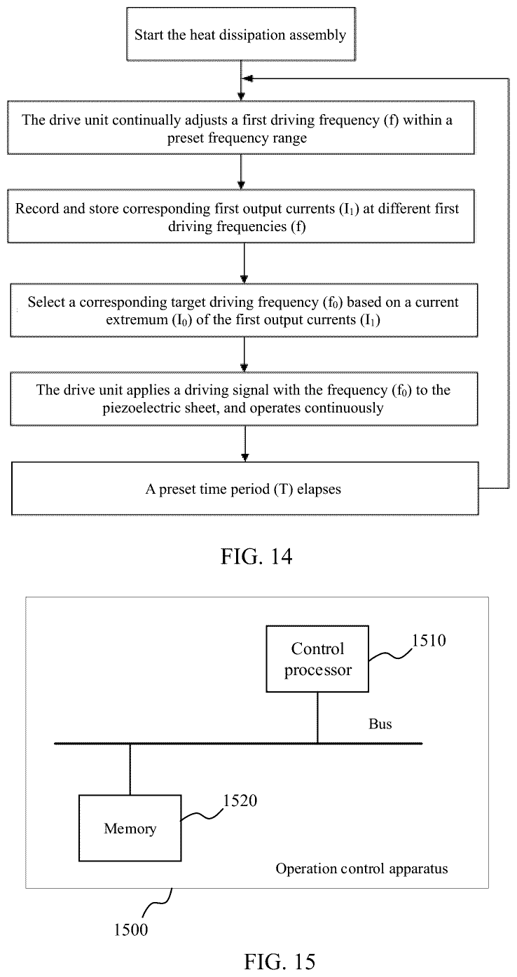

Embodiment two: As shown in FIG. 14, the heat dissipation assembly is started, and the drive unit continually adjusts a first driving frequency f within a preset frequency range, records and stores corresponding first output currents I₁ at different first driving frequencies f, and selects a corresponding target driving frequency f₀ based on a current extremum I₀ of the first output currents I₁. The drive unit applies a driving signal with the frequency f₀ to the piezoelectric sheet, operates continuously, and after a preset time period T elapses, searches for a target driving frequency f₀ again.

As shown in FIG. 4, in the control method for a heat dissipation assembly, 2N vibration plate units 200 are provided and divided into two vibration plate arrays 500 each including N vibration plate units 200, where N≥1. The control method for a heat dissipation assembly further includes:
applying driving signals with opposite phases to vibration plate units 200 located in different arrays, respectively.

In this embodiment, when an even number (2N) of vibration plate units 200 are arranged, the 2N vibration plate units 200 may be divided into two vibration plate arrays 500 each includes N vibration plate units 200. During driving, the drive unit 300 applies driving signals with opposite phases to vibration plate units 200 in different arrays, respectively. By controlling phase values of the driving signals of different vibration plate units 200, symmetrical vibration can be formed to reduce overall vibration of the heat dissipation assembly 100, thereby reducing noise generated by resonance between the heat dissipation assembly 100 and a heat dissipator 600.

As shown in FIG. 5, in the control method for a heat dissipation assembly, 2N+1 vibration plate units 200 are provided and divided into two vibration plate arrays 500, and the two vibration plate arrays 500 respectively include N+1 vibration plate units 200 and N vibration plate units 200, where N≥1. The control method for a heat dissipation assembly further includes:
applying driving signals with opposite phases to vibration plate units 200 located in different arrays, respectively.

In this embodiment, when an odd number (2N+1) of vibration plate units 200 are arranged, the 2N+1 vibration plate units 200 may be divided into two vibration plate arrays 500, with one array including include N+1 vibration plate units 200, and the other array including N vibration plate units 200. During operation, the drive unit 300 applies driving signals with opposite phases to vibration plate units 200 in different arrays, respectively. By controlling phase values of the driving signals of different vibration plate units 200, symmetrical vibration can be formed to reduce overall vibration of the heat dissipation assembly 100, thereby reducing noise generated by resonance between the heat dissipation assembly 100 and a heat dissipator 600.

It should be noted that a plurality of vibration plate units 200 are arranged. In this embodiment of the present disclosure, two forms, namely, an even number of vibration plate units 200 and an odd number of vibration plate units 200 are adopted. The vibration plate units 200 are divided into two arrays, and driving voltages with opposite phases are respectively applied thereto, that is, the vibration plate units 200 are driven in portions, which can greatly reduce operating noise.

An embodiment of a fourth aspect of the present disclosure provides a communication device, including the heat dissipation assembly 100 or the heat dissipator 600 in the foregoing embodiments.

The communication device provided in this embodiment includes the heat dissipation assembly 100 or the heat dissipator 600 in the foregoing embodiments. The heat dissipator 600 is provided with the heat dissipation assembly 100. The vibration plate unit 200 is formed by connecting a vibration plate 210 and a piezoelectric sheet 220. When a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210 to increase a wind speed of the heat dissipation assembly 100, and greatly improve a heat dissipation capability.

The communication device in this embodiment of the present disclosure may be an outdoor communication device with high reliability and noise requirements such as an AAU or an RRU, or may be an indoor communication device such as a Building Base Band Unit (BBU).

As shown in FIG. 15, an embodiment of a fifth aspect of the present disclosure provides an operation control apparatus 1500, including at least one control processor 1510 and a memory 1520 configured to be communicatively connected to the at least one control processor 1510. The memory 1520 stores instructions executable by the at least one control processor 1510 which, when executed by the at least one control processor 1510, causes the at least one control processor 1510 to carry out the control method for a heat dissipation assembly in the foregoing embodiments.

In the operation control apparatus provided in this embodiment, when a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210 to increase a wind speed of the heat dissipation assembly 100, and greatly improve a heat dissipation capability.

An embodiment of a sixth aspect of the present disclosure provides a computer-readable storage medium, storing computer-executable instructions which, when executed by a computer, causes the computer to implement the control method for a heat dissipation assembly in the foregoing embodiments.

In the computer-readable storage medium provided in this embodiment, when a trigger condition is met, the drive unit 300 searches for a target driving frequency within a preset frequency range. A first driving frequency output to the piezoelectric sheet 220 is continually changed within the given preset frequency range to obtain a plurality of first output currents corresponding to the first driving frequency, and then the target driving frequency is determined. The drive unit 300 applies a driving voltage to the piezoelectric sheet 220 based on the target driving frequency. The drive unit 300 intelligently adjusts the target driving frequency output to the piezoelectric sheet 220, which can increase an amplitude of the vibration plate 210 to increase a wind speed of the heat dissipation assembly 100, and greatly improve a heat dissipation capability.

The embodiments of the present disclosure include a heat dissipation assembly and a control method therefor, an apparatus, a heat dissipator, and a communication device. The heat dissipation assembly includes a vibration plate unit and a drive unit. The vibration plate unit is provided with a vibration plate and at least one piezoelectric sheet connected to the vibration plate. The drive unit is electrically connected to the vibration plate unit, and the drive unit is configured to: when a trigger condition is met, adjust a first driving frequency output to the piezoelectric sheet within a preset frequency range to obtain a plurality of corresponding first output currents, determine a target driving frequency based on the plurality of first output currents, and apply a driving voltage to the piezoelectric sheet based on the target driving frequency. According to the schemes provided in the embodiments of the present disclosure, in the embodiments, the vibration plate unit is formed by connecting a vibration plate and a piezoelectric sheet. When a trigger condition is met, the drive unit searches for a target driving frequency within a preset frequency range. A first driving frequency output to the piezoelectric sheet is continually changed within the given preset frequency range to obtain a plurality of first output currents corresponding to the first driving frequency, and then the target driving frequency is determined. The drive unit applies a driving voltage to the piezoelectric sheet based on the target driving frequency. The drive unit intelligently adjusts the target driving frequency output to the piezoelectric sheet, which can increase an amplitude of the vibration plate to increase a wind speed of the heat dissipation assembly, and greatly improve a heat dissipation capability.

The embodiments of the present disclosure are described in detail above with reference to the accompanying drawings, but the present disclosure is not limited thereto. Various changes can be made within the knowledge scope of those having ordinary skills in the art without departing from the protection scope of the present disclosure.

1. A heat dissipation assembly, comprising:
a vibration plate unit, provided with a vibration plate and at least one piezoelectric sheet connected to the vibration plate; and
a drive unit, electrically connected to the vibration plate unit, and the drive unit is configured to:
adjust, in response to meeting a trigger condition, a first driving frequency output to the piezoelectric sheet within a preset frequency range to obtain a plurality of corresponding first output currents, determine a target driving frequency based on the plurality of first output currents, and
apply a driving voltage to the piezoelectric sheet based on the target driving frequency.

2. The heat dissipation assembly of claim 1, wherein determining a target driving frequency based on the plurality of first output currents comprises:
determining a current extremum based on the plurality of first output currents; and
determining a corresponding target driving frequency based on the current extremum.

3. The heat dissipation assembly of claim 2, wherein the trigger condition comprises at least one of the following that:
the heat dissipation assembly is started; or
a second output current of the drive unit is detected when the heat dissipation assembly operates continuously, and a difference between the second output current and the current extremum exceeds a preset difference range; or
a continuous operation time of the heat dissipation assembly reaches a preset time period after the target driving frequency is determined each time.

4. The heat dissipation assembly of claim 1, further comprising a fastening structure, wherein the vibration plate unit is connected to the fastening structure, and
the vibration plate has one end connected to the fastening structure and the other end overhanging.

5. The heat dissipation assembly of claim 4, wherein the piezoelectric sheet is arranged at an end of the vibration plate connected to the fastening structure.

6. The heat dissipation assembly of claim 1, wherein one side of the vibration plate is provided with the piezoelectric sheet, or
two sides of the vibration plate are both provided with the piezoelectric sheet.

7. The heat dissipation assembly of claim 1, wherein 2N vibration plate units are provided and divided into two vibration plate arrays each comprising N vibration plate units, and
the drive unit is further configured to apply driving signals with opposite phases to vibration plate units located in different arrays respectively, wherein N≥1.

8. The heat dissipation assembly of claim 1, wherein 2N+1 vibration plate units are provided and divided into two vibration plate arrays,
the two vibration plate arrays respectively comprise N+1 vibration plate units and N vibration plate units, and
the drive unit is further configured to apply driving signals with opposite phases to vibration plate units located in different arrays respectively, wherein N≥1.

9. The heat dissipation assembly of claim 4, wherein a plurality of vibration plate units are provided and arranged in an array along a first direction and a second direction of the fastening structure.

10. A heat dissipator, comprising a heat dissipation assembly, the heat dissipation assembly comprising:
a vibration plate unit, provided with a vibration plate and at least one piezoelectric sheet connected to the vibration plate; and
a drive unit, electrically connected to the vibration plate unit, and the drive unit is configured to:
adjust, in response to meeting a trigger condition, a first driving frequency output to the piezoelectric sheet within a preset frequency range to obtain a plurality of corresponding first output currents,
determine a target driving frequency based on the plurality of first output currents, and
apply a driving voltage to the piezoelectric sheet based on the target driving frequency.

11. The heat dissipator of claim 10, wherein the heat dissipator is provided with a base, and
the heat dissipation assembly is mounted on the heat dissipator along a normal direction of the base, or
the heat dissipation assembly is mounted on the heat dissipator along a direction parallel to the base.

12. A control method for a heat dissipation assembly, wherein the heat dissipation assembly is provided with a vibration plate unit and a drive unit electrically connected to the vibration plate unit, and
the vibration plate unit is provided with a vibration plate and at least one piezoelectric sheet connected to the vibration plate; and the control method comprises:
adjusting, in response to meeting a trigger condition, a first driving frequency output to the piezoelectric sheet within a preset frequency range to obtain a plurality of corresponding first output currents;
determining a target driving frequency based on the plurality of first output currents; and
applying a driving voltage to the piezoelectric sheet based on the target driving frequency.

13. The control method of claim 12, wherein determining a target driving frequency based on the plurality of first output currents comprises:
determining a current extremum based on the plurality of first output currents; and
determining a corresponding target driving frequency based on the current extremum.

14. The control method of claim 13, wherein the trigger condition comprises at least one of the following that:
the heat dissipation assembly is started; or
a second output current of the drive unit is detected when the heat dissipation assembly operates continuously, and a difference between the second output current and the current extremum exceeds a preset difference range; or
a continuous operation time of the heat dissipation assembly reaches a preset time period after the target driving frequency is determined each time.

15. The control method of claim 12, wherein 2N vibration plate units are provided and divided into two vibration plate arrays each comprising N vibration plate units, wherein N≥1, and
the control method further comprises:
applying driving signals with opposite phases to vibration plate units located in different arrays, respectively.

16. The control method of claim 12, wherein 2N+1 vibration plate units are provided and divided into two vibration plate arrays,
the two vibration plate arrays respectively comprise N+1 vibration plate units and N vibration plate units, wherein N≥1, and
the control method further comprises:
applying driving signals with opposite phases to vibration plate units located in different arrays, respectively.

17. A communication device, comprising the heat dissipation assembly of claim 1.

18. An operation control apparatus, comprising at least one control processor and a memory configured to be communicatively connected to the at least one control processor, wherein the memory stores instructions executable by the at least one control processor which, when executed by the at least one control processor, causes the at least one control processor to carry out the control method of claim 12.

19. A non-transitory computer-readable storage medium, storing computer-executable instructions which, when executed by a computer, cause the computer to carry out the control method of claim 12.

20. A communication device, comprising the heat dissipator of claim 10.
